(19) United States
(12) Patent Application Publication
(10) Pub. No.: US 2016/0071800 A1
(43) Pub. Date: Mar. 10, 2016

(54) SEMICONDUCTOR STRUCTURE AND PROCESS THEREOF

(71) Applicant: UNITED MICROELECTRONICS CORP., Hsin-Chu City (TW)

(72) Inventors: Ching-Wen Hung, Tainan City (TW); Tsung-Hung Chang, Yunlin County (TW); Yi-Hui Lee, Taipei City (TW); Chih-Sen Huang, Tainan City (TW); Yi-Wei Chen, Taichung City (TW); Chia Chang Hsu, Kaohsiung City (TW); Hsin-Fu Huang, Tainan City (TW); Chun-Yuan Wu, Yun-Lin County (TW); Shih-Fang Tzou, Tainan City (TW)

(21) Appl. No.: 14/513,230

(22) Filed: Oct. 14, 2014

(30) Foreign Application Priority Data
Sep. 5, 2014 (TW) 103130905

(51) Int. Cl. H01L 23/535; H01L 21/768

(52) U.S. Cl. CPC H01L 23/535; H01L 21/76895; H01L 21/76879

(57) ABSTRACT

A semiconductor structure including a dielectric layer, a titanium layer, a titanium nitride layer and a metal is provided. The dielectric layer is disposed on a substrate, wherein the dielectric layer has a via. The titanium layer covers the via, wherein the titanium layer has tensile stress lower than 1500 Mpa. The titanium nitride layer conformally covers the titanium layer. The metal fills the via. The present invention also provides a semiconductor process for forming said semiconductor structure. The semiconductor process includes the following steps. A dielectric layer is formed on a substrate, wherein the dielectric has a via. A titanium layer conformally covers the via, wherein the titanium layer has compressive stress lower than 500 Mpa. A titanium nitride layer is formed to conformally cover the titanium layer. A metal fills the via.

### BACKGROUND OF THE INVENTION

1. Field of the Invention

The present invention relates generally to a semiconductor structure and process thereof, and more specifically to a semiconductor structure and process thereof, which forms a titanium layer having compressive stress lower than 500 Mpa.

2. Description of the Prior Art

Field effect transistors are important electronic devices in integrated circuits. As the size of semiconductor devices becomes smaller, the fabrication of the transistors has improved. Manufacturing techniques must be constantly enhanced to fabricate transistors of smaller size and higher quality. In the conventional method for fabricating transistors, a gate structure is first formed on a substrate, and a lightly doped drain (LDD) is then formed on the two corresponding sides of the gate structure. A spacer is formed on the sidewall of the gate structure and an ion implantation process is performed to form a source/drain region within the substrate by utilizing the gate structure and spacer as a mask. In order to incorporate the gate, source, and drain into the circuit, contact plugs are utilized for interconnection purposes. Each contact plug includes a barrier layer surrounding a low resistivity material to prevent the low resistivity material from diffusing outward to other areas. As the miniaturization of semiconductor devices increases, filling a barrier layer of low resistivity into a contact hole to form the contact plug can maintain or enhance the performance of formed semiconductor devices.

### SUMMARY OF THE INVENTION

The present invention provides a semiconductor structure and process thereof, which forms a titanium layer having compressive stress lower than 500 Mpa, and then forms a titanium nitride layer. Formation of a semiconductor structure which generates bubbles and splashes and pollutes structures in other areas due to a high processing temperature for forming the titanium nitride layer can thereby be avoided.

The present invention provides a semiconductor structure including a dielectric layer, a titanium layer, a titanium nitride layer and a metal. The dielectric layer is disposed on a substrate, wherein the dielectric layer has a via. The titanium layer covers the via, wherein the titanium layer has tensile stress lower than 1500 Mpa. The titanium nitride layer conformally covers the titanium layer. The metal fills the via.

The present invention provides a semiconductor process including the following steps. A dielectric layer is formed on a substrate, wherein the dielectric layer has a via. A titanium layer is formed to conformally covers the via, wherein the titanium layer has compressive stress lower than 500 Mpa. A titanium nitride layer is formed to conformally cover the titanium layer. Finally, a metal fills the via.

As shown by the above, the present invention provides a semiconductor structure and process thereof, which forms a titanium layer having compressive stress lower than 500 Mpa, so that the titanium layer can maintain a tensile stress lower than 1500 Mpa even when undergoing processes having high processing temperatures, such as a process for forming a titanium nitride layer on the titanium layer or a process for forming a silicide in a source/drain. Formation of a semiconductor structure which generates bubbles and splashes that may pollute structures in other areas and reduce yields thereof, can be avoided.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 schematically depict a cross-sectional view of a semiconductor process according to a first embodiment of the present invention.

FIGS. 9-10 schematically depict a cross-sectional view of a semiconductor process according to a second embodiment of the present invention.

### DETAILED DESCRIPTION

FIGS. 1-8 schematically depict a cross-sectional view of a semiconductor process according to a first embodiment of the present invention. As shown in FIG. 1, a substrate 110 is provided. The substrate 110 may be a semiconductor substrate such as a silicon substrate, a silicon containing substrate, a III-V group-on-silicon (such as GaN-on-silicon) substrate, a graphene-on-silicon substrate, or a silicon-on-insulator (SOI) substrate. Isolation structures 10 may be formed in the substrate 110 to electrically isolate each MOS transistor. The isolation structures 10 may be shallow trench isolation structures, but are not limited thereto.

A MOS transistor M is formed on/in the substrate 110. The MOS transistor M may include a gate G on the substrate 110. In this embodiment, the gate G is a metal gate, which may be formed by replacing a sacrificial gate such as a polysilicon gate through a metal gate replacement process. In another embodiment, the gate G may be a polysilicon gate, depending upon practical needs. The gate G may include a stacked structure including a dielectric layer 122, a work function layer 124 and a low resistivity material 126 stacked from bottom to top. The dielectric layer 122 may include a selective barrier layer (not shown) and a dielectric layer having a high dielectric constant, wherein the selective barrier layer may be an oxide layer formed through a thermal oxide process or a chemical oxide process, and the dielectric layer having a high dielectric constant may be the group selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalite (SrBi₂Ta₂O₉, SBT), lead zirconate titanate (PbZrₓTi₁-xO₃, PZT) and barium strontium titanate (BaₓSr₁-xTiO₃, BST). The work function layer 124 may be a single layer or a multilayer, composed of titanium nitride (TiN), titanium carbide (TiC), tantalum nitride (TaN), tantalum carbide (TaC), tungsten carbide (WC), titanium aluminide (TiAl) or aluminum titanium nitride (TiAlN). The low resistivity material 126 may be composed of aluminum, tungsten, titanium aluminum (TiAl) alloy, cobalt tungsten phosphide (CoWP), but it is not limited thereto. Barrier layers (not shown) may be selectively formed between the dielectric layer 122, the work function layer 124 or the low resistivity material 126, wherein the barrier layers may be single layers or multilayers composed of tantalum nitride (TaN) or titanium nitride (TiN).

The MOS transistor M may further include a spacer (not shown) on the substrate 110 beside the gate G, and a lightly doped source/drain 132, a source/drain 134 and an epitaxial structure 136 in the substrate 110 beside the gate G (or the spacer). The lightly doped source/drain 132 and the source/drain 134 may be doped by trivalent ions or pentavalent ions such as boron or phosphorus; the epitaxial structure 136 maybe a silicon germanium epitaxial structure or a silicon carbide epitaxial structure, depending upon the electrical type of the MOS transistor M.

A contact etch stop layer 140 and a dielectric layer 150 are located on the substrate 110 and expose the gate G. The contact etch stop layer 140 may be a nitride layer or a doped nitride layer having a capability of inducing stress to a gate channel C below the gate G; the dielectric layer 150 may be an oxide layer, but it is not limited thereto. A cap layer 20 may optionally cover the gate G, the contact etch stop layer 140 and the dielectric layer 150 to protect the gate G from being damaged during later processes. The cap layer 20 may be an oxide layer, but it is not limited thereto.

The methods of forming the structure of FIG. 1 are known in the art, and are therefore not described herein. Since a gate-last for high-K last process is applied in this embodiment, the dielectric layer 122 has a U-shaped cross-sectional profile. In another embodiment, the present invention may be applied in a gate-last for high-K first process or a gate-first process.

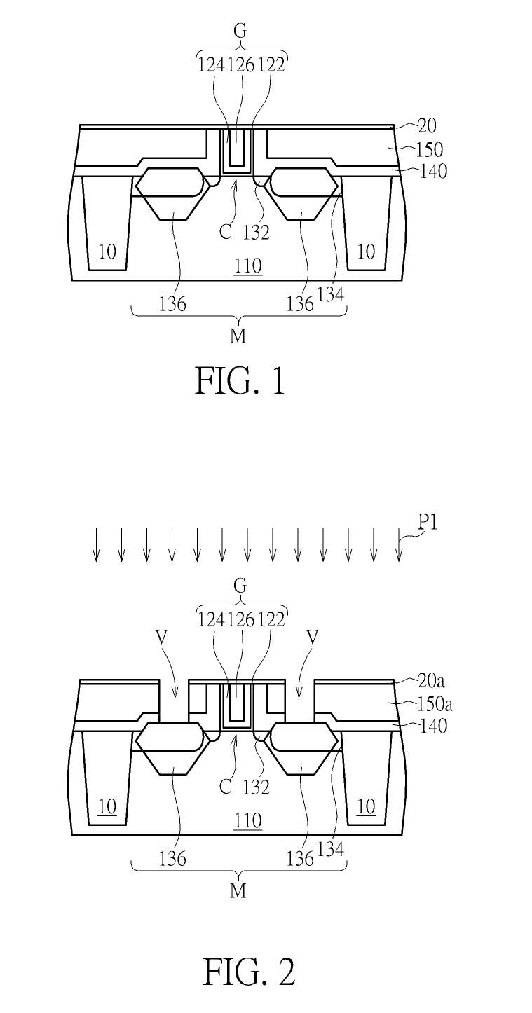

After the dielectric layer 150 is formed, a plurality of vias V are formed in the dielectric layer 150 to expose the source/drain 134 in the substrate 110, thereby a cap layer 20a and a dielectric layer 150a are formed, as shown in FIG. 2. The vias V may be formed by an etching process. In this embodiment, the vias V may be contact holes used for forming contact plugs by filling metal therein. In another embodiment, the present invention maybe applied to a through silicon via (TSV), a via or a recess process. Only cross-sectional views of the contact holes in this embodiment are depicted in the figures, but the contact holes can also be formed by double-patterning methods. A cleaning process P1 may be optionally performed to clean vias V. The cleaning process P1 may be a pre-cleaning process of a silicide including at least a wet or a dry cleaning process, which may be a wet cleaning process containing dilute hydrofluoric acid (DHF) or deionized water, a dry cleaning process containing SICONI (Trademark of Applied Materials, Inc.) or an argon bombardment dry cleaning process, but is not limited thereto. The cleaning process P1 may further include a vapor removing process with a processing temperature of 360° C.

As shown in FIG. 3, a titanium layer 162 conformally covers the vias V and the dielectric layer 150a. It is emphasized that the titanium layer 162 of the present invention as-deposited has compressive stress lower than 500 Mpa. Preferably, the titanium layer 162 has compressive stress lower than 300 Mpa. The titanium layer 162 will therefore not have a tensile stress larger than 1500 Mpa when forming a titanium nitride layer or performing an annealing process. The titanium layer 162 (or at least a part which transforms into a silicide in a later silicide process) will be prevented from generating bubbles caused by high stress. As these bubbles split, splashes maybe generated which pollute other areas, leading to short circuits, particularly for dense areas such as static random-access memory (SRAM) areas. Yields are therefore reduced. In one case, the titanium layer 162 is formed by sputtering, and the processing temperature maybe room temperature, but is not limited thereto. The titanium layer 162 can have compressive stress lower than 500 Mpa by reducing bias of the sputtering process. Furthermore, the reduction of bias of the sputtering process not only can form the titanium layer 162 having compressive stress lower than 500Mpa, but can also improve the filleting problem of tops T1 of the vias V. Contact plugs formed later can be prevented from contacting each other, which leads to short circuits.

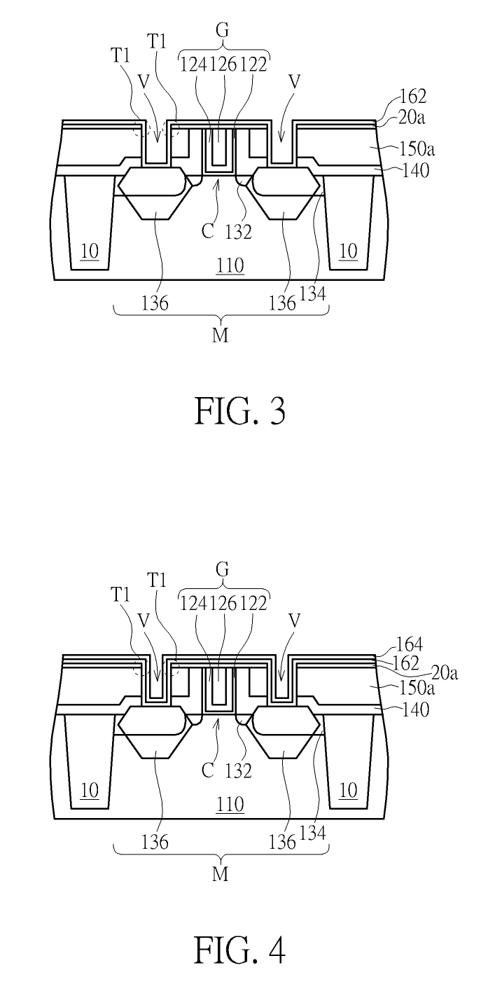

As shown in FIG. 4, a titanium nitride layer 164 is formed to conformally cover the titanium layer 162. In one case, the titanium nitride layer 164 is formed by a metal-organic chemical vapor deposition process. The processing temperature of forming the titanium nitride layer 164 is higher than room temperature, such as 400° C., to induce tensile stress of the titanium layer 162. As the tensile stress is too high, bubbles are generated in the titanium layer 162. Because the titanium layer 162 of the present invention has compressive stress lower than 500 Mpa, the titanium layer 162 can still have tensile stress lower than 1500 Mpa after the titanium nitride layer 164 is formed. Therefore, generation of bubbles is prevented.

As shown in FIG. 5, a silicide 170 may be formed between the titanium nitride layer 164 and substrate 110. Since the vias V of the present invention are aligned to expose the source/drain 134 in the substrate 110, the source/drain 134 must be directly below the titanium nitride layer 164; the silicide 170 is therefore located in/on the source/drain 134. The silicide 170 maybe a silicon titanium silicide. In detail, an annealing process P2 may be performed to transform at least a part of the titanium layer 162 and a part of the substrate 110 below the titanium layer 162 into the silicon titanium silicide.

In this embodiment, only a part of the titanium layer 162 is transformed into the silicon titanium silicide, and a part of the titanium layer 162 between the silicon titanium silicide and the titanium nitride layer 164 is reserved. In another embodiment, all of the titanium layer 162 may transform into the silicon titanium silicide. The silicon titanium silicide is located between the titanium nitride layer 164 and the substrate 110, and contacts the titanium nitride layer 164.

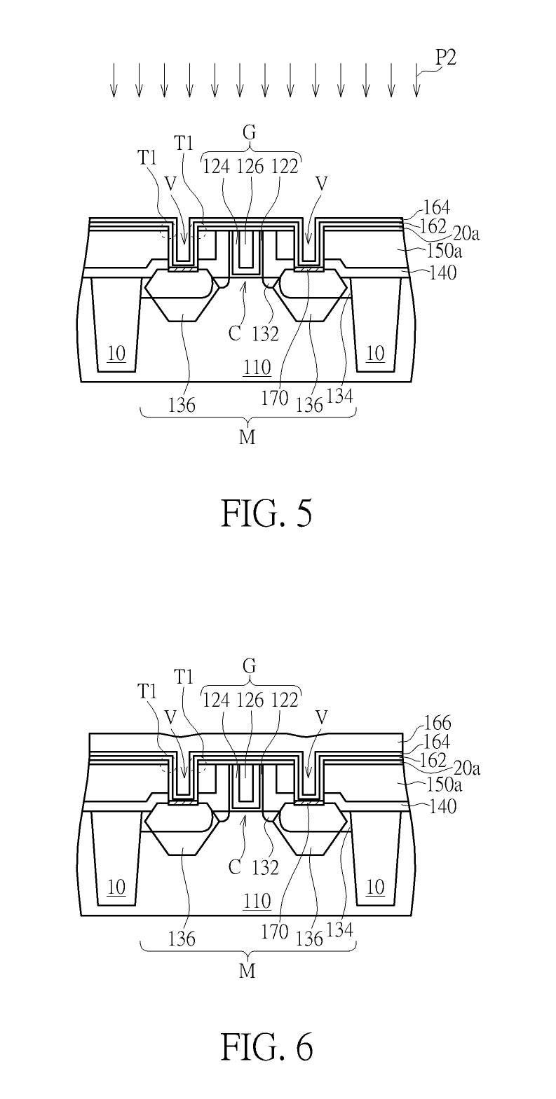

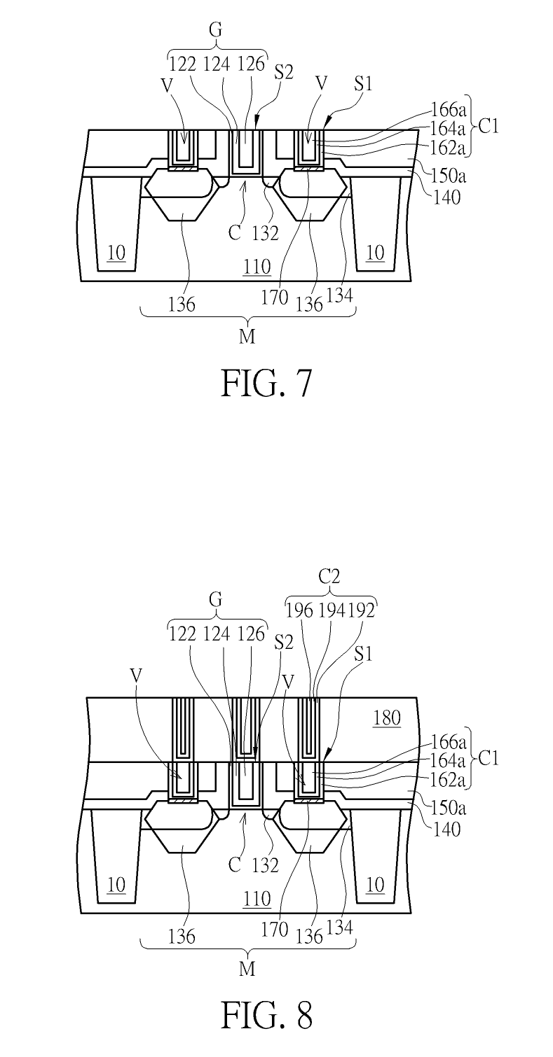

As shown in FIG. 6, a metal 166 covers the vias V and the titanium nitride layer 164. In this embodiment, the metal 166 is composed of tungsten. In another embodiment, the metal 166 may be composed of aluminum or copper. A planarization process may be performed to planarize the metal 166, the titanium nitride layer 164 and the titanium layer 162 until the dielectric layer 150a is exposed to form a plurality of contact plugs C1 in the vias V, wherein each of the contact plugs C1 include a titanium layer 162a, a titanium nitride layer 164a and a metal 166a, as shown in FIG. 7. In this way, a top surface S1 of the contact plugs C1 can trim a top surface S2 of the gate G. The planarization process may be a chemical mechanical polishing (CMP) process, but is not limited thereto.

Other semiconductor processes may then be performed. As shown in FIG. 8, after the contact plugs C1 are formed in the dielectric layer 150a, a dielectric layer 180 may be formed to blanket the dielectric layer 150a, the contact plugs C1 and the gate G, wherein the dielectric layer 180 may have a plurality of contact plugs C2 physically contacting the contact plugs C1 and the gate G to form electrical connections outward to other external circuits. In this embodiment, the dielectric layer 150a may be an inter dielectric layer having the MOS transistor M formed therein while the dielectric layer 180 may be an inter-metal dielectric having metal interconnects formed therein. The methods of forming the dielectric layer 180 and the contact plugs C2 are similar to the methods of forming the dielectric layer 150a and the contact plugs C1, wherein the difference is that an annealing process for forming a silicide is not performed when forming the dielectric layer 180 and the contact plugs C2. More precisely, a dielectric layer (not shown) may be formed and planarized, and an etching process may then be performed to form a plurality of contact holes (not shown) in the dielectric layer to expose the contact plugs C1 and the gate G. Then, a titanium layer having compressive stress lower than 500 Mpa, a titanium nitride layer and a metal sequentially cover each of the contact holes and the dielectric layer; thereafter, the metal, the titanium nitride layer and the titanium layer are planarized to form the contact plugs C2. In this way, the present invention can also prevent bubbles that lead to splashes and pollution of other areas from being generated in the titanium layer when forming the titanium nitride layer in the contact plugs C2.

The contact plugs C1 in the dielectric layer 150a are formed first, and then the contact plugs C2 in the dielectric layer 180 are formed. The method of the present invention can be applied to prevent the titanium layer formed in the contact plugs C1 and the contact plugs C2 from generating bubbles and splashes.

A second embodiment applying the present invention is presented in the following. The second embodiment forms the dielectric layer 150a and the dielectric layer 180, and then forms contact plugs on the source/drain 134 and the gate G at the same time.

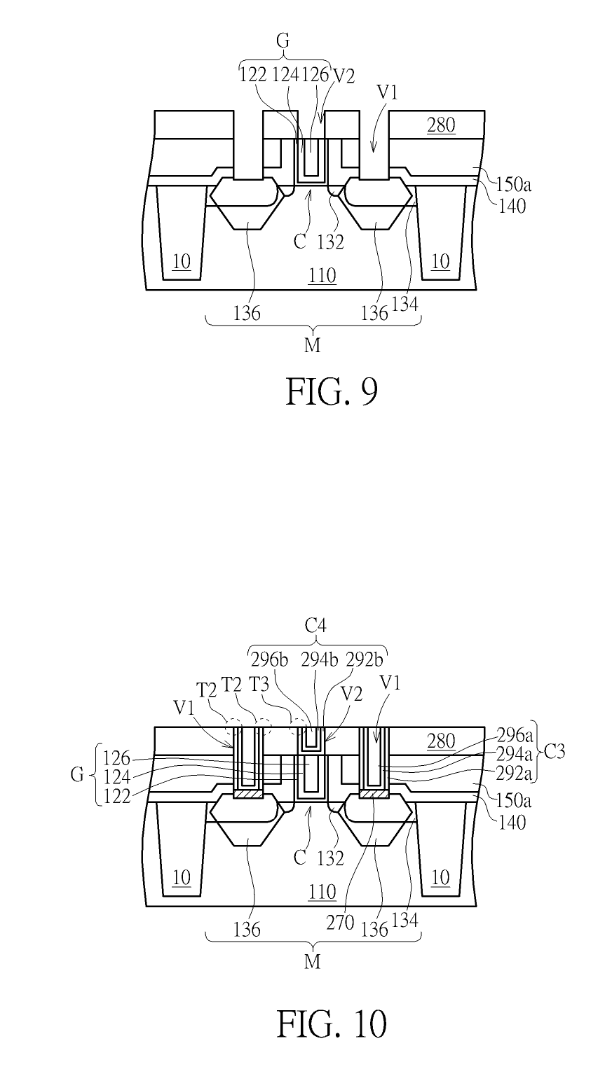

Processes of the second embodiment which are the same as those of the first embodiment are not described again. A dielectric layer (not shown) covers the gate G and the dielectric layer 150, and the dielectric layer is then planarized; thereafter, an etching process may be performed to form a plurality of contact holes V1 and V2 in the dielectric layer and the dielectric layer 150 at the same time, to form the dielectric layer 150a and a dielectric layer 280, as shown in FIG. 9. The contact holes V1 expose the source/drain 134 while the contact holes V2 expose the gate G.

As shown in FIG. 10, a plurality of contact plugs C3 and C4 are formed in the contact holes V1 and V2 at the same time by applying the aforesaid methods of the present invention. A cleaning process P1 may be optionally performed to clean the contact holes V1 and V2. The cleaning process P1 may be a pre-cleaning process of a silicide including at least a wet or a dry cleaning process, which may be a wet cleaning process containing dilute hydrofluoric acid (DHF) or deionized water, a dry cleaning process containing SICONI (Trademark of Applied Materials, Inc.) or an argon bombardment dry cleaning process, but is not limited thereto. The cleaning process P1 may further include a vapor removing process with a processing temperature of 360° C. A titanium layer (not shown) and a titanium nitride layer (not shown) may be sequentially formed to conformally cover the contact holes V1 and V2 and the dielectric layer 280. An annealing process may be performed to form a silicide 270 between the titanium nitride layer and the substrate 110. A metal (not shown) covers the contact holes V1 and V2 and the dielectric layer 280. The metal, the titanium nitride layer and the titanium layer may be planarized to form the contact plugs C3 and C4. Each of the contact plugs C3 include a titanium layer 292a, a titanium nitride layer 294a and a metal 296a while the contact plugs C4 include a titanium layer 292b, a titanium nitride layer 294b and a metal 296b.

It is emphasized that the titanium layer of the present invention has compressive stress lower than 500 Mpa. Preferably, the titanium layer has compressive stress lower than 300 Mpa. The titanium layer will therefore not have a tensile stress larger than 1500 Mpa when a titanium nitride layer is formed or an annealing process is performed. The titanium layer (or at least a part of the titanium layer which transforms to a silicide in a later silicide process) will not generate bubbles caused by high stress. As these bubbles split, splashes may be generated which pollute other areas, leading to short circuits, particularly for dense areas such as static random-access memory (SRAM) areas. Thereby, yields are reduced. In one case, the titanium layer is formed by sputtering, and the processing temperature may be room temperature, but is not limited thereto. The titanium layer can have compressive stress lower than 500 Mpa by reducing bias of the sputtering process. The reduction of bias of the sputtering process not only forms the titanium layer having compressive stress lower than 500 Mpa, but also improves the filleting problem of tops T2 and T3 of the contact holes V1 and V2, so that contact plugs C3 and C4 formed therein can be prevented from contacting each other, which leads to short circuits.

In this embodiment, as the silicide 270 is formed by the annealing process, only the titanium layer contacting the substrate 110 will transform into the silicide 270 while the titanium layer contacting the gate G will not transform into a silicide. As shown in FIG. 10, the bottom of the contact plugs C3 totally transform into the silicide 270 while the bottom of the contact plugs C4 do not transform into a silicide. In another embodiment, only parts of the bottom of the contact plugs C3 transform into the silicide 270 while the other part of the bottom of the contact plugs C3 are reserved.

To summarize, the present invention provides a semiconductor structure and process thereof, which forms a titanium layer having compressive stress lower than 500 Mpa, so that the titanium layer will have tensile stress lower than 1500 Mpa even when undergoing processes having high processing temperatures such as a process for forming a titanium nitride layer on the titanium layer or a process for forming a silicide in a source/drain. Formation of a semiconductor structure which generates bubbles and splashes to pollute structures in other areas and reduce yields can thereby be avoided.

The titanium layer having compressive stress lower than 500 Mpa may be formed by a sputtering process having a low sputtering bias; the processing temperature may be room temperature; the titanium nitride layer may be formed by a metal-organic chemical vapor deposition process; and the silicide may be formed by an annealing process to directly transform the titanium layer and the substrate into a silicon titanium silicide.

The present invention is applied in contact plug processes in the first and second embodiments; however, the present invention can also be applied to other processes such as a through silicon via (TSV), a recess process or a via process.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor structure, comprising:
a dielectric layer disposed on a substrate, wherein the dielectric layer has a via;
a titanium layer covering the via, wherein the titanium layer has tensile stress lower than 1500 Mpa;
a titanium nitride layer conformally covering the titanium layer; and
a metal filling the via.

2. The semiconductor structure according to claim 1, wherein the via comprises a contact hole, and the titanium layer, the titanium nitride layer and the metal constitute a contact plug.

3. The semiconductor structure according to claim 1, further comprising:
a silicide disposed between the titanium nitride layer and the substrate.

4. The semiconductor structure according to claim 3, wherein the silicide comprises a silicon titanium silicide.

5. The semiconductor structure according to claim 3, further comprising:
a gate disposed on the substrate beside the via; and
a source/drain disposed in the substrate below the titanium layer, and the silicide disposed on the source/drain.

6. The semiconductor structure according to claim 1, further comprising:
a gate disposed directly below the titanium layer and contacting the titanium layer.

7. The semiconductor structure according to claim 1, wherein the metal comprises tungsten.

8. The semiconductor structure according to claim 1, wherein the dielectric layer comprises an interdielectric layer.

9. A semiconductor process, comprising:
forming a dielectric layer on a substrate, wherein the dielectric layer has a via;
forming a titanium layer conformally covering the via, wherein the titanium layer has compressive stress lower than 500 Mpa;
forming a titanium nitride layer conformally covering the titanium layer; and
filling a metal in the via.

10. The semiconductor process according to claim 9, wherein the titanium layer has compressive stress lower than 300 Mpa.

11. The semiconductor process according to claim 9, wherein the titanium layer is formed by sputtering.

12. The semiconductor process according to claim 9, wherein the titanium nitride layer is formed by a metal-organic chemical vapor deposition process.

13. The semiconductor process according to claim 12, wherein the processing temperature of forming the titanium nitride layer is 400° C.

14. The semiconductor process according to claim 9, further comprising:
forming a silicide between the titanium nitride layer and the substrate after the titanium nitride layer is formed.

15. The semiconductor process according to claim 14, wherein the step of forming the silicide comprises:
performing an annealing process to transform at least a part of the titanium layer and a part of the substrate into a silicon titanium silicide.

16. The semiconductor process according to claim 9, further comprising:
performing a cleaning process to clean the via after the dielectric layer is formed.

17. The semiconductor process according to claim 9, wherein the via comprises a contact hole, and the titanium layer, the titanium nitride layer and the metal constitute a contact plug.

18. The semiconductor process according to claim 17, further comprising:
forming a gate on the substrate; and
forming a source/drain in the substrate beside the gate before the dielectric layer is formed, wherein the gate is located beside the via and the source/drain is located in the substrate directly below the titanium nitride layer.

19. The semiconductor process according to claim 17, further comprising:
forming a gate on the substrate before the dielectric layer is formed, wherein the gate is disposed directly below the titanium layer and contacts the titanium layer.

20. The semiconductor process according to claim 9, wherein the titanium layer having compressive stress lower than 500 Mpa has tensile stress lower than 1500 Mpa after the titanium nitride layer is formed.
